(19) United States
(12) Patent Application Publication
(10) Pub. No.: US 2015/0076516 A1
(43) Pub. Date: Mar. 19, 2015

(54) SEMICONDUCTOR DEVICE AND SEMICONDUCTOR MODULE

(71) Applicant: Kabushiki Kaisha Toshiba, Tokyo (JP)

(72) Inventors: Yuuji Hisazato, Tokyo (JP); Hiroki Sekiya, Kanagawa-ken (JP); Yo Sasaki, Saitama-ken (JP); Kazuya Kodani, Kanagawa-ken (JP); Nobumitsu Tada, Tokyo (JP); Hitoshi Matsumura, Kanagawa-ken (JP); Tomohiro Iguchi, Kanagawa-ken (JP)

(73) Assignee: Kabushiki Kaisha Toshiba, Tokyo (JP)

(21) Appl. No.: 14/202,588

(22) Filed: Mar. 10, 2014

(30) Foreign Application Priority Data
Sep. 13, 2013 (JP) 2013-191176

(51) Int. Cl. H01L 23/00

(52) U.S. Cl. CPC H01L 23/562
USPC 257/77; 257/76

(57) ABSTRACT

According to one embodiment, a semiconductor device includes a semiconductor element and a metal film. The semiconductor element has a first surface and a second surface opposite to the first surface. The metal film is provided above the second surface of the semiconductor element. The metal film includes Cr.

### CROSS-REFERENCE TO RELATED APPLICATIONS

This application is based upon and claims the benefit of priority from Japanese Patent Application No. 2013-191176, filed on Sep. 13, 2013; the entire contents of which are incorporated herein by reference.

### FIELD

Embodiments described herein relate generally to a semiconductor device and a semiconductor module.

### BACKGROUND

To mount a semiconductor element on a substrate, a bonding material such as solder is used to connect both. When a load such as cooling/heating cycles and power cycles is applied for a long time to a semiconductor module in which such a semiconductor element is housed in a package, a crack may occur in the bonding portion. If the crack progresses, breaking of the bonding portion will occur and this will be a cause of malfunction, such as melting of the bonding portion due to an increase in temperature resistance. For the semiconductor device and the semiconductor module, it is important to improve the reliability.

### BRIEF DESCRIPTION OF THE DRAWINGS

FIG. 1A and FIG. 1B are schematic cross-sectional views illustrating the configuration of a semiconductor device according to a first embodiment;

FIG. 2 is a schematic cross-sectional view illustrating a mounting state of the semiconductor device 110;

FIG. 3 is a view illustrating the change of the thickness of metal films obtained by a constant temperature test;

FIG. 4 is a schematic cross-sectional view illustrating the configuration of a semiconductor module according to a second embodiment;

FIG. 5 is a schematic plan view illustrating a mounting state in the semiconductor module;

FIG. 6A and FIG. 6B are views illustrating an intermediate layer;

FIG. 7A and FIG. 7B are views showing a reference example; and

FIG. 8A and FIG. 8B are schematic cross-sectional views illustrating the configurations of intermediate layers.

### DETAILED DESCRIPTION

According to one embodiment, a semiconductor device includes a semiconductor element and a metal film. The semiconductor element has a first surface and a second surface opposite to the first surface. The metal film is provided above the second surface of the semiconductor element. The metal film includes Cr.

Various embodiments will be described hereinafter with reference to the accompanying drawings. In the following description, identical components are marked with the same reference numerals, and a description of components once described is omitted as appropriate.

### First Embodiment

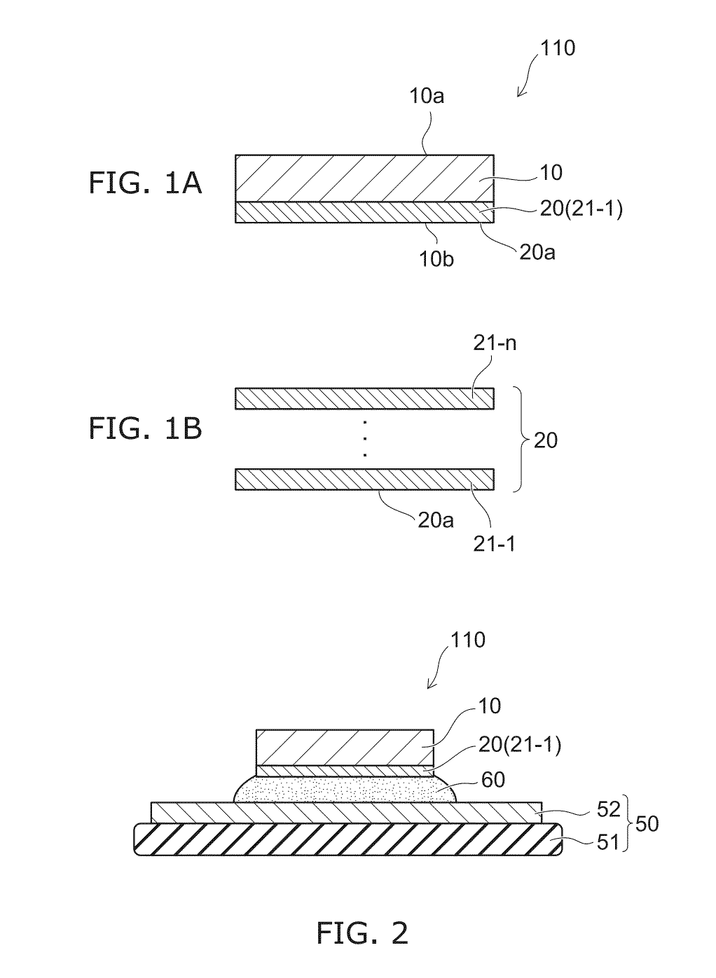

FIG. 1A and FIG. 1B are schematic cross-sectional views illustrating the configuration of a semiconductor device according to a first embodiment.

FIG. 1A shows a cross-sectional view of the whole of a semiconductor device 110. FIG. 1B shows an enlarged cross-sectional view of a metal film 20 of the semiconductor device 110.

As shown in FIG. 1A, the semiconductor device 110 according to the embodiment includes a semiconductor element 10 and a metal film 20.

The semiconductor element 10 includes an element region formed by performing a prescribed impurity implantation process, photolithography process, etc. on a semiconductor material. The element region is an active element such as a transistor and a diode, or a passive element such as a resistance and a capacitor. The semiconductor element 10 is in a rectangular chip form cut out of a wafer or the like including a semiconductor material. The semiconductor element 10 has a first surface 10a and a second surface 10b on the opposite side to the first surface 10a. The first surface 10a is the front surface of the semiconductor element 10, for example, and the second surface 10b is the back surface of the semiconductor element 10, for example.

The metal film 20 is provided on (above) the second surface 10b of the semiconductor element 10. The metal film 20 is in contact with the second surface 10b. The metal film 20 includes at least a 1st film 21-1. As shown in FIG. 1B, the 1st film 21-1 is provided on the outermost surface 20a side of the metal film 20. In the semiconductor device 110, the outermost surface 20a includes chromium (Cr). In the embodiment, substantially pure Cr or a metal (alloy) including Cr is used as the 1st film 21-1. The substantially pure Cr includes Cr in which an impurity is mixed unintentionally.

The metal film 20 may be a single-layer film of only the 1st film 21-1. The metal film 20 may be also a multiple-layer film.

As shown in FIG. 1B, in the case where the metal film 20 is a multiple-layer film of n layers (n being an integer of 2 or more), the metal film 20 includes the 1st film 21-1 to the n-th film 21-n. Of the n layers of the multiple-layer film, the film farthest from the second surface 10b of the semiconductor element 10 is taken as the 1st film 21-1. From the 1st film 21-1 toward the second surface 10b, the 2nd film 21-2, the 3rd film 21-3, . . . are placed in this order. The film in contact with the second surface 10b is the n-th film 21-n.

In the case where the metal film 20 is a multiple-layer film of n layers, at least one of the 2nd film 21-2 to the n-th film 21-n includes at least one selected from the group consisting of titanium (Ti), aluminum (Al), gold (Au), tin (Sn), nickel (Ni), and silver (Ag).

Specific examples of the metal film 20 will now be illustrated.

An example of n=2, that is, a multiple-layer film of two layers is illustrated.

The 2nd film 21-2 is Au, and the 1st film 21-1 is Cr.

An example of n=3, that is, a multiple-layer film of three layers is illustrated.

The 3rd film 21-3 is Ti, the 2nd film 21-2 is Au, and the 1st film 21-1 is Cr.

An example of n=4, that is, a multiple-layer film of four layers is illustrated.

The 4th film 21-4 is Al, the 3rd film 21-3 is Ti, the 2nd film 21-2 is Au, and the 1st film 21-1 is Cr.

Another example of n=4, that is, another multiple-layer film of four layers is illustrated.

The 4th film 21-4 is Al, the 3rd film 21-3 is Ti, the 2nd film 21-2 is Sn, and the 1st film 21-1 is Cr.

The thickness of the 1st film 21-1 including Cr is approximately not less than 500 nanometers (nm) and not more than 750 nm, for example.

The metal film 20 is formed by vacuum deposition, sputtering, ion plating, or electric plating, for example. In the case where Cr is used as the 1st film 21-1, it is preferably formed by a dry manufacturing method in a reduced pressure environment in order to suppress the oxidation of the surface.

FIG. 2 is a schematic cross-sectional view illustrating a mounting state of the semiconductor device 110.

As shown in FIG. 2, the semiconductor device 110 is mounted on a substrate 50. The substrate 50 includes a support unit 51 and a conductive pattern 52. A ceramic is used for the support unit 51, for example. Copper (Cu) is used for the conductive pattern 52, for example.

The semiconductor device 110 is bonded to the conductive pattern 52 of the substrate 50 via a bonding material 60. Solder including tin (Sn) is used as the bonding material 60, for example. Alternatively, the bonding material 60 may be an intermetallic compound including silver (Ag) nanoparticles, a silver (Ag) sintered material, tin copper (SnCu), silver tin (Ag₃Sn), or the like.

When a current is passed through the semiconductor element 10 in the operation of the semiconductor device 110, the temperature of the semiconductor element 10 is increased, for example. On the other hand, when the operation of the semiconductor device 110 is stopped, the temperature of the semiconductor element 10 is decreased. If the operation and stopping of the semiconductor device 110 are repeated, distortion will occur in the solder that is the bonding material 60. Then, a crack may occur and progress due to the recrystallization of the solder.

As another factor, in the case where a resin mold is provided around the semiconductor device 110, the mold portion may be peeled off from a base substrate for heat dissipation. Consequently, the overall binding is lost; thus, a crack may occur and progress in the bonding portion of solder or the like.

The heat of the semiconductor device 110 is conducted to not only the bonding portion but also the conductive pattern 52 and the support unit 51 of the substrate 50, which are the constituent materials of the underlying portion. Cu may soften when it is used at high temperature or when heat generation occurs due to an increase in thermal resistance. This softening occurs when the temperature of Cu is increased to the recrystallization temperature or more.

For the semiconductor element 10 in the semiconductor device 110, a material having an operation-guaranteed temperature higher than the highest temperature at which the operation of an element of Si is guaranteed (the operation-guaranteed temperature of the element of Si) is used. For example, the material of the semiconductor element 10 includes one of SiC and GaN. Materials such as SiC and GaN used for power modules are expected to be used at a very high temperature. For example, Si has a limit of use temperature range of 175° C., whereas SiC and GaN can be used in a temperature range exceeding 200° C. or 250° C.

In the semiconductor device 110 used in such high temperatures, the loss of the metal film 20 is effectively suppressed by using the metal film 20 including the 1st film 21-1 including Cr as the outermost surface 20a.

The reliability of the bonding portion in the case where the semiconductor device 110 and the substrate 50 are bonded together via the bonding material 60 is verified by cooling/heating cycles, power cycles, a constant temperature test, or the like. There is a case where, when a load is applied to the bonding portion, a crack occurs in the bonding material 60; and when the load is continued, the crack progresses.

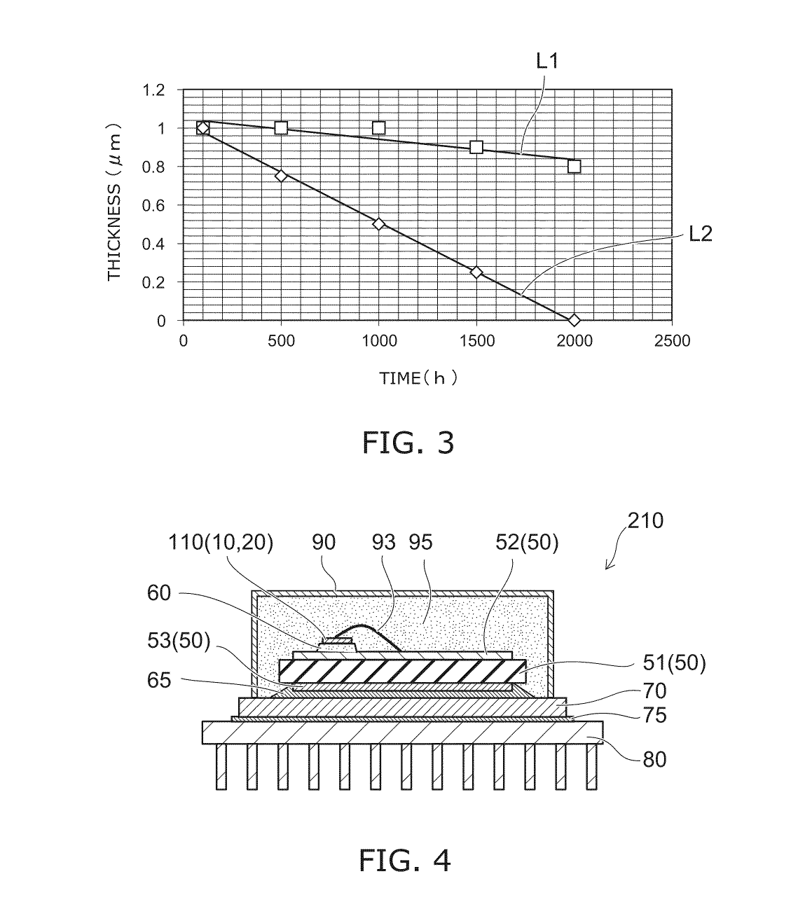

FIG. 3 is a view illustrating the change of the thickness of metal films obtained by a constant temperature test.

The horizontal axis of FIG. 3 is time, and the vertical axis is the thickness of the metal film. Line L1 shown in FIG. 3 shows the thickness of the metal film 20 used in the semiconductor device 110 according to the embodiment, and line L2 shows the thickness of a metal film in the case where a metal film including Ni is used as the outermost surface. In the constant temperature test, the change of the thickness of the metal film when samples are allowed to stand in a constant temperature oven of 200° C. for 2000 hours is measured.

As shown by line L1 of FIG. 3, it is found that, in the metal film 20 used in the semiconductor device 110 according to the embodiment, the decrease in the thickness of the metal film 20 is suppressed more than line L2. That is, as shown by line L2, in the case where a metal film including Ni is used, the thickness of the metal film decreases gradually. On the other hand, as shown by line L1, in the case where the metal film 20 including Cr is used, the thickness of the metal film 20 is not decreased so much

This is because in the case where a metal film including Ni is used, Sn included in the bonding material 60 forms a compound with Ni, and is diffused and lost. If the Ni of the metal film is lost, a crack is likely to occur due to the deformation of the metal film, and this causes a reduction in the reliability of the bonding portion. In contrast, in the case where the metal film 20 including Cr is used, since Sn included in the bonding material 60 is less likely to form a compound with Cr, the decrease in the thickness of the metal film 20 due to loss is suppressed. When the decrease in the thickness of the metal film 20 is suppressed, the reliability of the bonding portion of the semiconductor device 110 is improved.

Thus, in the semiconductor device 110 according to the embodiment, the thickness of the metal film 20 can be maintained even if the metal film 20 is exposed to a temperature of 200° C. or more, for example. Therefore, the reliability can be improved in the long-term use at high temperature when the semiconductor device 110 is used by being mounted on the substrate 50.

Although in the embodiment Cr is illustrated as the material included in the outermost surface 20a of the metal film 20, any material other than Cr is possible to the extent that it does not form or is less likely to form a compound with the material of the bonding material 60. Furthermore, the material included in the outermost surface 20a of the metal film 20 may be a material that is not lost or is less likely to be lost even if it is exposed to a temperature higher than the operation-guaranteed temperature of Si.

### Second Embodiment

Next, a semiconductor module according to a second embodiment is described.

FIG. 4 is a schematic cross-sectional view illustrating the configuration of a semiconductor module according to the second embodiment.

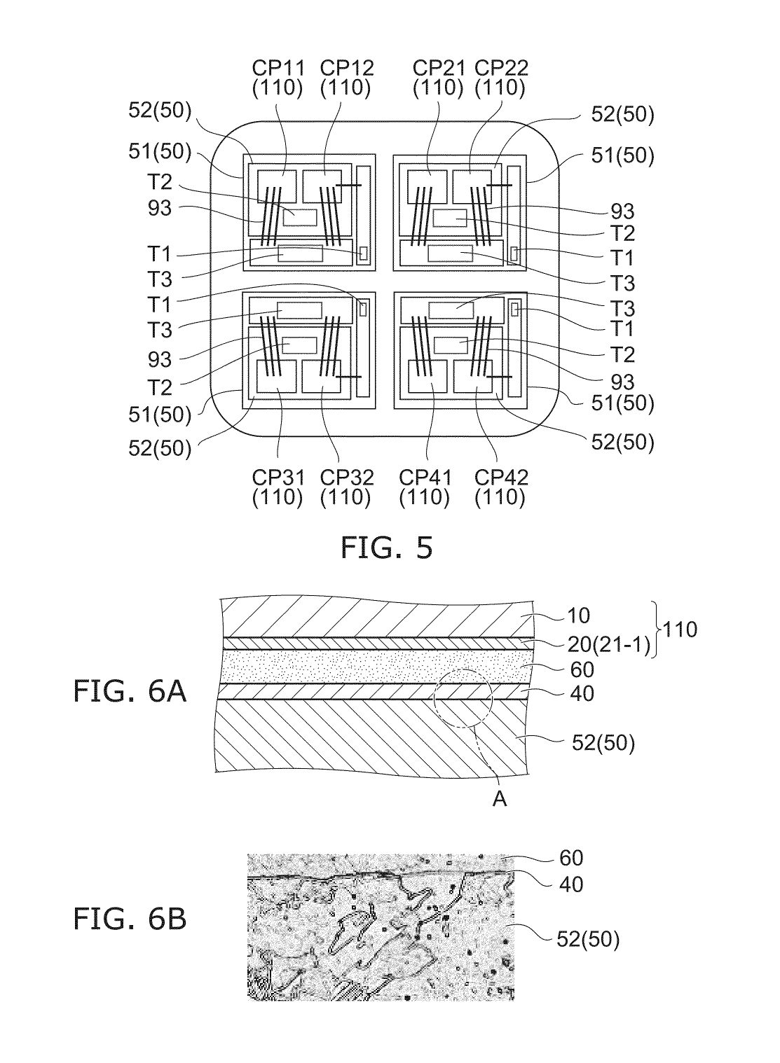

FIG. 5 is a schematic plan view illustrating a mounting state in a semiconductor module.

As shown in FIG. 4, a semiconductor module 210 includes the semiconductor device 110, the substrate 50, and the bonding material 60. In the example shown in FIG. 4, the semiconductor module 210 further includes a base plate 70, a heat sink 80, and a case 90.

As described in the first embodiment, the semiconductor device 110 includes the semiconductor element 10 and the metal film 20. The semiconductor device 110 is mounted on the substrate 50. The bonding material 60 is provided between the metal film 20 of the semiconductor device 110 and the conductive pattern 52 of the substrate 50.

Although in FIG. 4 one semiconductor device 110 is shown in the semiconductor module 210, a plurality of semiconductor devices 110 may be included. For example, in the example shown in FIG. 5, a plurality of semiconductor devices CP11, CP12, CP21, CP22, CP31, CP32, CP41, and CP42 are provided as semiconductor devices 110 in the semiconductor module 210.

In the example shown in FIG. 5, two semiconductor devices 110 are mounted on one substrate 50. That is, in the example shown in FIG. 5, four substrates 50 are provided, and two semiconductor devices 110 are mounted on each substrate 50.

The semiconductor devices CP12, CP22, CP32, and CP42 are power transistors (for example, IGBTs; insulated gate bipolar transistors), for example. The semiconductor devices CP11, CP21, CP31, and CP41 are power diodes (for example, FRDs; fast recovery diodes), for example.

Each of the semiconductor devices CP11, CP12, CP21, CP22, CP31, CP32, CP41, and CP42 is electrically connected to the conductive pattern 52 via a bonding wire 93.

In each substrate 50, a terminal T1 that is a gate, a terminal T2 that is a collector, and a terminal T3 that is an emitter are provided, for example. The semiconductor devices CP11, CP12, CP21, CP22, CP31, CP32, CP41, and CP42 form a prescribed circuit such as an inverter.

As shown in FIG. 4, the substrate 50 is mounted on the base plate 70. A conductive film 53 is provided on the back surface of the support unit 51 of the substrate 50. The conductive film 53 of the substrate 50 is bonded onto the base plate 70 via a bonding material 65 such as solder.

The heat sink 80 may be provided on the lower surface of the base plate 70. The heat sink 80 is connected to the lower surface of the base plate 70 via, for example, thermal grease 75.

On the base plate 70, the substrate 50, the semiconductor device 110, and the bonding wire 93 are surrounded by the case 90. A gel 95 for protection and heat dissipation may be put in the case 90.

In the semiconductor module 210 like this, high reliability of the bonding portion between the semiconductor device 110 and the substrate 50 can be maintained even when the semiconductor device 110 becomes high temperature. In particular, in the case where a plurality of semiconductor devices 110 are provided in the semiconductor module 210 as shown in FIG. 5, the temperature in the case 90 is likely to become high. Sufficient reliability is ensured even in the semiconductor module 210 including a plurality of semiconductor devices 110.

Next, an intermediate layer 40 is described.

FIG. 6A and FIG. 6B are views illustrating an intermediate layer.

FIG. 6A shows a schematic cross-sectional view showing an arrangement example of the intermediate layer 40. FIG. 6B shows a schematic cross-sectional view illustrating the state of the structure in the A portion of FIG. 6A.

The semiconductor module 210 may include the intermediate layer 40.

As shown in FIG. 6A, the intermediate layer 40 is provided between the 1st film 21-1 of the metal film 20 and the conductive pattern 52 of the substrate 50. The intermediate layer 40 has a thermal conductivity lower than the thermal conductivity of the conductive pattern 52. The intermediate layer 40 may be disposed in any position between the 1st film 21-1 and the conductive pattern 52. In the case where Cu is used as the conductive pattern 52, stainless steel is used for the intermediate layer 40, for example. The thickness of the intermediate layer 40 is approximately 10 micrometers (μm).

By providing the intermediate layer 40, the property of blocking the heat that is conducted from the semiconductor element 10 to the conductive pattern 52 via the metal film 20 and the bonding material 60 is enhanced as compared to the case where the intermediate layer 40 is not provided. Thereby, heat is less likely to be released to the outside via the substrate 50. Therefore, components (for example, the gel 95) existing outside the substrate 50 and inside the case 90 can be protected from the influence due to heat, for example. In the case where the intermediate layer 40 is provided, since heat is blocked and the temperature of the semiconductor element 10 is increased, the metal film 20 preferably includes Cr. Thereby, as described above, the decrease in the thickness of the metal film 20 is lessened and the occurrence of a crack is suppressed.

In the embodiment, a material that can operate at high temperature, such as SiC and GaN, is used as the material of the semiconductor element 10. Therefore, even when the intermediate layer 40 is provided and the thermal conductivity to the substrate 50 side is reduced, the operation of the semiconductor element 10 is not influenced.

For the semiconductor module 210 including the intermediate layer 40 like this, a cycle in which the temperature of the semiconductor element 10 is increased and decreased between 100° C. and 200° C. by current passage and current cut-off is performed 50,000 cycles. Then, the conductive pattern 52 becomes a structure like that shown in FIG. 6B. Cu is used for the conductive pattern 52.

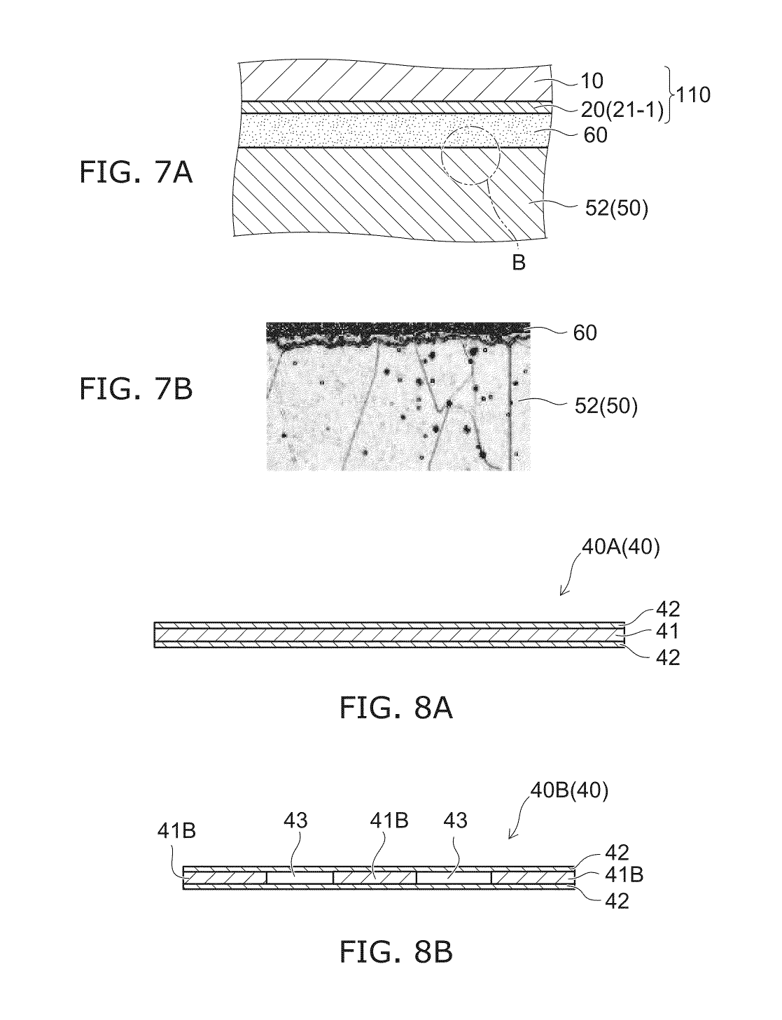

FIG. 7A and FIG. 7B are views showing a reference example.

FIG. 7A shows a schematic cross-sectional view showing an arrangement example not including the intermediate layer 40. FIG. 7B shows a schematic cross-sectional view illustrating the state of the structure in the B portion of FIG. 7A. When a cycle of temperature increase and decrease similar to the above is performed 50,000 cycles for the reference example, the conductive pattern 52 becomes a structure like that shown in FIG. 7B.

As shown in FIG. 6B, it is found that in the example including the intermediate layer 40, the initial crystal grains in the Cu of the conductive pattern 52 remain and there is little influence of the thermal cycles. On the other hand, as shown in FIG. 7B, it is found that in the reference example not including the intermediate layer 40, the crystal grains in the Cu of the conductive pattern 52 have grown greatly as compared to the crystal grains of FIG. 6B.

In the example including the intermediate layer 40, the crack progress rate of the bonding material 60 is approximately 15%. On the other hand, in the example not including the intermediate layer 40, the crack progress rate of the bonding material 60 is approximately 85%. Here, the crack progress rate is the ratio of the length of the crack to the bonding length of the bonding material 60 bonding the semiconductor device 110 and the substrate 50.

Thus, by providing the intermediate layer 40, the composition change of the conductive pattern 52 is suppressed, and high reliability in the long-term use of the semiconductor module 210 is obtained.

FIG. 8A and FIG. 8B are schematic cross-sectional views illustrating the configurations of intermediate layers.

An intermediate layer 40A shown in FIG. 8A includes an intermediate member 41 and outside members 42. The intermediate layer 40A has a structure in which the intermediate member 41 is sandwiched by two outside members 42. Stainless steel with a thickness of approximately 10 μm is used for the intermediate member 41, for example. Ni with a thickness of approximately 10 μm is used for the outside member 42, for example. Since an oxide film is formed on the surface of stainless steel, a structure in which the intermediate member 41 made of stainless steel is sandwiched by the outside members 42 of Ni is employed. Thereby, peeling between layers during use is suppressed.

An intermediate layer 40B shown in FIG. 8B includes an intermediate member 41B and outside members 42. The intermediate layer 40B has a structure in which the intermediate member 41B is sandwiched by two outside members 42. The intermediate member 41B has a configuration in which hollow portions 43 are provided in parts of the intermediate member 41 shown in FIG. 8A. The intermediate member 41B is stainless steel foil provided with a plurality of holes, for example. The hole forms the hollow portion 43. In the structure having the hollow portion 43 in it like the intermediate layer 40B, heat is effectively blocked by the hollow portion 43.

By using the intermediate layers 40A and 40B like these, a semiconductor module 210 with higher reliability is obtained.

In the semiconductor module 210 using the intermediate layers 40, 40A, and 40B, a material other than Cr (for example, Ni or Ag) may be used as the material included in the outermost surface 20a side of the metal film 20.

As described above, the embodiment can provide a semiconductor device and a semiconductor module with improved reliability.

Although the embodiment are described above, the invention is not limited to these examples. For example, additions, deletions, or design modifications of components or appropriate combinations of the features of the embodiments appropriately made by one skilled in the art in regard to the embodiments described above are within the scope of the invention to the extent that the purport of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor element having a first surface and a second surface opposite to the first surface; and
a metal film provided above the second surface of the semiconductor element and including chromium (Cr).

2. The device according to claim 1, wherein the semiconductor element includes a material having an operation-guaranteed temperature higher than an operation-guaranteed temperature of silicon (Si).

3. The device according to claim 2, wherein the material includes one of silicon carbide (SiC) and gallium nitride (GaN).

4. The device according to claim 1, wherein the metal film includes a first film provided above an outermost surface side and including chromium (Cr) and a second film provided between the first film and the second surface.

5. The device according to claim 4, wherein the second film includes at least one selected from the group consisting of titanium (Ti), aluminum (Al), gold (Au), tin (Sn), nickel (Ni), and silver (Ag).

6. The device according to claim 4, wherein the second film is a multiple-layer film and at least one of the layers of the multiple-layer film includes at least one selected from the group consisting of titanium (Ti), aluminum (Al), gold (Au), tin (Sn), nickel (Ni), and silver (Ag).

7. A semiconductor module comprising:
a semiconductor device including a semiconductor element having a first surface and a second surface opposite to the first surface and a metal film provided above the second surface of the semiconductor element and including chromium (Cr);
a substrate having a conductive pattern; and
a bonding material provided between the metal film and the conductive pattern.

8. The module according to claim 7, wherein the conductive pattern includes copper (Cu).

9. The module according to claim 7, wherein the bonding material includes tin (Sn) or silver (Ag).

10. The module according to claim 7, further comprising an intermediate layer provided between the metal film and the conductive pattern and having a thermal conductivity lower than a thermal conductivity of the conductive pattern.

11. The module according to claim 10, wherein the intermediate layer includes stainless steel.

12. The module according to claim 10, wherein
the intermediate layer includes an intermediate member and a pair of outside members,
the intermediate member is sandwiched by the pair of outside members,
the intermediate member includes the stainless steel, and
the outside member includes nickel (Ni).

13. The module according to claim 10, wherein a hollow portion is provided at a part of the intermediate layer.

14. The module according to claim 13, wherein
the intermediate layer includes an intermediate member and a pair of outside members,
the intermediate member is sandwiched by the pair of outside members, and
a hollow portion is provided at the intermediate member.

15. The module according to claim 14, wherein the hollow portion is a hole provided at the intermediate member.

16. The module according to claim 7, wherein the semiconductor element includes a material having an operation-guaranteed temperature higher than an operation-guaranteed temperature of silicon (Si).

17. The module according to claim 7, wherein the material includes one of silicon carbide (SiC) and gallium nitride (GaN).

18. The module according to claim 7, wherein the metal film includes a first film provided above an outermost surface side and including chromium (Cr) and a second film provided between the first film and the second surface.

19. The module according to claim 18, wherein the second film includes at least one selected from the group consisting of titanium (Ti), aluminum (Al), gold (Au), tin (Sn), nickel (Ni), and silver (Ag).

20. The module according to claim 18, wherein the second film is a multiple-layer film and at least one of layers of the multiple-layer film includes at least one selected from the group consisting of titanium (Ti), aluminum (Al), gold (Au), tin (Sn), nickel (Ni), and silver (Ag).
